(19) United States
(12) Patent Application Publication
(10) Pub. No.: US 2021/0141022 A1
(43) Pub. Date: May 13, 2021

(54) METHOD FOR DETERMINING A STATE OF CHARGE OF A VEHICLE BATTERY OF A VEHICLE

(71) Applicant: SEG Automotive Germany GmbH, Stuttgart (DE)

(72) Inventors: Henning STÖCKLEIN, Eberdingen (DE); Kevin KUBELKA, Leonberg-Silberberg (DE); Jens MÜLLER, Bietigheim-Bissingen (DE); Peng QIAN, Stuttgart (DE); Matthias CWIK, Stuttgart (DE); Nima SAADAT, Stuttgart (DE)

(21) Appl. No.: 17/096,395

(22) Filed: Nov. 12, 2020

(30) Foreign Application Priority Data
Nov. 12, 2019 (DE) 102019130431.8

(51) Int. Cl. G01R 31/36; G01R 31/388

(52) U.S. Cl. CPC G01R 31/3644; G01R 31/388

(57) ABSTRACT

The present invention relates to a method for determining the state of charge of a vehicle battery (150) of a vehicle, a starter relay of a starting device (100) for an internal combustion engine of the vehicle for engaging a starter pinion in a ring gear of the internal combustion engine having a first winding (121) and a second winding (122) which can be controlled independently of one another, the first winding (121) being controlled in predetermined control states and voltage values that are established in the course of these control states being determined and the state of charge of the vehicle battery (150) being determined depending on the determined voltage values.

### CROSS-REFERENCE TO RELATED APPLICATIONS

This application claims the benefit of priority to German Patent Application No. 102019130431.8 filed Nov. 12, 2019, each of which is incorporated herein by reference in its entirety.

### DESCRIPTION

The present invention relates to a method for determining a state of charge of a vehicle battery of a vehicle.

### BACKGROUND OF THE INVENTION

Batteries in motor vehicles can be used to supply electric loads in an on-board electrical system and to start an internal combustion engine of the vehicle using a corresponding starting device. In this case, it may be important to know the current state of charge of the battery.

In the course of what is known as a start-stop operation, the internal combustion engine can be deactivated while the vehicle is in operation, for example at a red traffic light or during coasting operation, and restarted if necessary. In order to allow the internal combustion engine to be restarted effectively, it may be particularly important here to know the current state of charge of the vehicle battery.

### SUMMARY OF THE INVENTION

Against this background, the invention proposes a method for determining a state of charge of a vehicle battery of a vehicle, and a computing unit and a computer program for carrying out said method having the features of the independent claims. Advantageous embodiments are the subject of the dependent claims and the following description.

A starter relay of a starting device for an internal combustion engine of the vehicle is provided for engaging a starter pinion in a ring gear of the internal combustion engine. The starter relay has a first winding and a second winding, which can be controlled independently of one another and energized independently of one another. In the context of the present method, the first winding is controlled or energized in predetermined control states and voltage values that are established in the course of these control states are determined. The state of charge of the vehicle battery is determined depending on these determined voltage values. Expediently, in order to determine the state of charge only the first winding is therefore energized, while the second winding remains deactivated and is not energized. This has the advantage that the starter relay is not actuated and the method can therefore be carried out at any time.

The electromagnetic or electromechanical starter relay is also provided in particular to close a circuit between the electric starter motor and the vehicle battery. However, a separate switching relay may also be available for closing the motor circuit. By energizing the first and second winding, in particular a lifting armature can be set in motion, which is coupled to the starter pinion via an engagement lever. If the starter relay combines pull-in and switching functions, a contact plate can in particular also be pressed against two mating contacts in order to close the circuit of the starter motor. The first and second windings can expediently be provided as pull-in and hold-in windings, respectively, with both the pull-in winding and the hold-in winding being energized in particular to actuate the starter relay (i.e. pulling in the armature); however, it is sufficient to control only the hold-in winding to hold the armature in the actuated state.

In particular, an electronic pilot control relay can also be provided for controlling the starter relay and thus the first and second windings. For example, this pilot control relay can include a computing unit such as a microcontroller and switching elements, in particular semiconductor switches, which can be controlled thereby. Furthermore, the pilot control relay can expediently be in data-transmitting connection with a control unit of the vehicle. A first switching element is expediently provided for controlling or energizing the first winding, and a second switching element for controlling the second winding. In particular, these switching elements allow independent control and energization of the windings.

Since the two windings can be controlled independently of one another, there is the possibility of only briefly energizing one of the two windings independently of a starting process of the internal combustion engine, without the risk of damaging the corresponding switching elements. Briefly energizing only one winding in such a manner can cause in particular an evaluable voltage drop. The present method proposes a concept to control the first winding independently of the second winding in the course of the predetermined control states in such a way that the current state of charge of the vehicle battery can be inferred precisely from the voltage values that are established.

The energization of the first winding can in particular be carried out independently of a starting process of the internal combustion engine, so that the determination of the state of charge in the course of the method is expediently also possible during regular operation or while the vehicle or internal combustion engine is at a standstill.

Alternatively, in order to determine the state of charge of a vehicle battery, a voltage profile on the battery can be recorded during a starting process of the relevant internal combustion engine and evaluated together with further measured variables, for example by a battery management system. In addition, a temperature of the vehicle battery can be recorded for this purpose, for example a battery acid temperature in the case of a lead-acid battery. Such a determination of the battery state can, however, be carried out only when the corresponding starter is switched on, so that the state of charge can usually only be determined looking back at the most recently carried out starting process. It is not possible to determine the state of charge independently of a start process.

The present invention now provides a possibility of being able to determine the state of charge of the vehicle battery independently of starting processes at any time, expediently also while the vehicle is in operation. In particular, in the course of the method, voltage values are determined which are already recorded for closed-loop and/or open-loop control of the starting device, so that expediently no additional measurement effort is required. Furthermore, in particular no temperature measurement is necessary, in particular no measurement of the battery temperature, and therefore a corresponding temperature sensor can be omitted.

The determination of the state of charge can in particular be carried out by the pilot control relay, in particular by the microcontroller of this pilot control relay. In particular, a battery management system for determining the state of charge can therefore also be dispensed with. In this case, the pilot control relay can, for example, carry out other functions relating to the vehicle battery, such as implementing a battery model or estimating the battery acid temperature.

In particular, the first winding consists of an alloy with a low temperature coefficient of electrical resistance. The resistance of the winding is therefore expediently almost independent of the component temperature. This allows a precise voltage measurement while the winding is being energized and also a precise calculation of the internal resistance of the on-board electrical system.

The present invention expediently allows the state of charge of the vehicle battery to be precisely determined while the vehicle is in operation with the internal combustion engine deactivated, for example in the course of a start-stop operation. In vehicles with this type of start-stop operation, it may be of particular importance to determine the state of the vehicle battery as precisely as possible, for example to allow a precise prognosis of the voltage curve when the internal combustion engine is about to restart. Furthermore, if the internal combustion engine is frequently deactivated in the course of start-stop operation, the vehicle electrical system can be exposed to strong fluctuations in the state of charge. Even if the internal combustion engine is deactivated for a longer period of time, there may be fluctuations in the on-board electrical system status, and therefore it is advantageous to determine the battery charge status even when the internal combustion engine is deactivated. The present method is therefore particularly suitable for vehicles with start-stop operation.

The first winding is preferably not energized in the course of a first control state. In the course of a second and third control state, the first winding is preferably energized in different ways in each case. In the course of the first control state, an open-circuit voltage can expediently be determined. In the course of the second and third control states, the on-board electrical system can be loaded with two different load points, so that the state of charge of the battery can expediently be determined more precisely than by measuring the open-circuit voltage and a single load point. This takes into account, for example, the determination of the “extrapolated open-circuit voltage” of lead-acid batteries, which is relevant for the state of charge. Vehicle batteries of this type have a higher open-circuit voltage without or with a very low current load.

According to a particularly advantageous embodiment, the first winding is not energized in the course of the first control state and a first voltage value is determined. In particular, the current value of the on-board electrical system voltage (battery voltage) is determined as this first voltage value. The first voltage value between the terminal 30 (power supply +) and the terminal 31 (power supply −, ground) can expediently be determined, for example by means of an analog-to-digital converter of the pilot control relay. This open-circuit voltage or the first voltage value is also referred to in the following as U_{30.0}.

The first winding is then advantageously energized with a first current level in the course of the second control state and a second voltage value is determined. The second voltage value is expediently determined after a current has built up through the first winding. In particular, the current value of the on-board electrical system voltage is determined as the second voltage value, expediently between the terminals 30 and 31. The second voltage value is also referred to in the following as U_{30.A}.

The first winding is then advantageously energized with a second current level in the course of the third control state, and a third voltage value and a fourth voltage value are determined. The third and fourth voltage values are also expediently determined after a current has built up through the first winding. A current value of the on-board electrical system voltage is expediently also determined as the third voltage value, in particular between the terminals 30 and 31. In particular, a current value of the voltage applied to or dropped at the first winding is determined as a fourth voltage value, expediently between a plus connection of the first winding and the terminal 31, for example between terminals 50 and 31. The third voltage value is referred to in the following as U_{30.B}, and the fourth voltage value as U_{EW}. After the third and fourth voltage values have been determined, the energization of the first winding can be ended. The state of charge of the vehicle battery is advantageously determined depending on the first voltage value U_{30.0}, the second voltage value U_{30.A}, the third voltage value U_{30.B} and the fourth voltage value U_{EW}.

Particularly advantageously, a resistance value, in particular the internal resistance of the on-board electrical system (vehicle battery and leads between the vehicle battery and the starting device) is determined depending on the second voltage value U_{30.A}, the third voltage value U_{30.B} and the fourth voltage value U_{EW}. The state of charge of the vehicle battery is advantageously determined depending on the first voltage value U_{30.0} and the resistance value. In the following, the resistance value is referred to in particular as R_{ges}.

The resistance value R_{ges} is determined depending on the second voltage value U_{30.A}, the third voltage value U_{30.B}, the fourth voltage value U_{EW} and the internal resistance R_{EW} of the first winding.

In particular, the resistance value can be determined by the microcontroller of the pilot control relay. A plausibility check can also be carried out by the microcontroller, and the results for the open-circuit voltage U_{30.0} and the resistance value R_{ges} can be transmitted to a control unit of the vehicle via a communication interface, e.g. CAN.

The different current levels are preferably produced by different pulse duty factors of the battery voltage on the first winding. For example, it would also be possible to provide the different current levels by differently controlling the switching elements in the pilot control relay. The first winding is preferably energized with high frequency in a clocked manner in the course of the second control state and is unclocked in the course of the third control state. For example, a pulse duty factor of 50:50 can be selected for the second control state and a pulse duty factor of 100% for the third control state. During the second control state, the on-board electrical system voltage expediently drops from the open-circuit voltage U_{30.0} to the lower second voltage value U_{30.A}. During the third control state, the on-board electrical system voltage expediently drops further from the second voltage value U_{30.A} to the lower third voltage value U_{30.B}.

The first winding is preferably energized in the course of the second control state and the third control state such that in the course of the second control state, a current through the first winding is set, the current strength of which is lower than in the course of the third control state. For example, the load current or the amperage through the first winding in the course of the second control state can be approximately half as great as in the course of the third control state.

The state of charge of the vehicle battery is preferably further determined depending on a predetermined calibration value which characterizes a lead resistance. This lead resistance is to be understood in particular as a resistance value of leads between the vehicle battery and the starting device. In particular, the determined resistance value R_{ges} is corrected for this purpose by the calibration value dependent on the lead resistance. The lead resistance between the vehicle battery and the starting device, in particular the plus-side and minus-side starter leads, is implicitly recorded within the scope of the present method. In order to allow an even more precise and in particular vehicle-specific determination of the state of charge, the lead resistance can be determined as a calibration value and subtracted from the determined total resistance R_{ges}. For temperature compensation of the line resistance, the pilot control relay can also expediently receive and take into account the ambient temperature from the on-board electrical system, for example by means of a CAN parameter of the temperature of the intake air temperature. For example, the calibration value can be determined in the course of starting up the vehicle and/or at regular service intervals under defined on-board electrical system conditions. The calibration value can expediently be stored in a non-volatile memory of the pilot control relay, in particular within the microcontroller.

Preferably, an admissibility check is first carried out, and if the admissibility check is positive, the first winding is preferably controlled in the predetermined control states and the state of charge of the vehicle battery is determined depending on the determined voltage values. For example, the pilot control relay can receive a request from the vehicle for determining the state of charge, for example from a control device of the vehicle, via a bidirectional communication interface, for example CAN. After recognizing this requirement, a plausibility check and the admissibility check for determining the state in the current status of the vehicle are expediently carried out. For example, the request can be assessed as impermissible during a starting process, a coasting down of the starter motor or a fault condition with regard to excessive temperature.

The first winding is advantageously a pull-in winding and the second winding is a hold-in winding. The pull-in winding is expediently connected to the positive supply connection of the battery via the pilot control relay and also in particular to the starter motor, in particular to an excitation winding of the starter motor. Expediently, only the pull-in winding is energized in order to determine the state of charge of the battery in the context of the present method, while the hold-in winding in particular remains de-energized.

According to a particularly advantageous embodiment, a first switching element is expediently provided for controlling the first winding, and a second switching element for controlling the second winding. These switching elements can in particular make it possible to independently control and energize the first and second windings. The first and second switching elements are arranged in particular in the pilot control relay for controlling the starter relay. In particular, these switching elements can be closed or opened by the microcontroller of the pilot control relay, whereby the first and second windings can expediently be controlled.

The first switching element and the second switching element are each advantageously designed as an output stage, preferably each as a semiconductor output stage or semiconductor switch. The switching elements are preferably each designed as a MOSFET. The design of the output stages allows the switched load to be switched on for a short time, which expediently allows both clocked control (for current limitation) and, in particular, energization of the winding for a few milliseconds without damaging the switching elements.

A computing unit according to the invention, for example a control device of a motor vehicle, is configured, in particular in terms of programming, to carry out a method according to the invention.

The implementation of a method according to the invention in the form of a computer program or computer program product having program code for carrying out all the method steps is advantageous, since this leads to particularly low costs, in particular if an executing control device is also used for other tasks and is therefore available anyway. Suitable data carriers for providing the computer program are, in particular, magnetic, optical and electrical memories such as hard drives, flash memories, EEPROMs, DVDs, etc. A program can also be downloaded via computer networks (Internet, intranet, etc.).

Further advantages and embodiments of the invention can be found in the description and the accompanying drawings.

The invention is shown schematically in the drawings on the basis of embodiments and is described below with reference to the drawings.

### BRIEF DESCRIPTION OF THE DRAWINGS

FIG. 1 schematically shows a starting device for an internal combustion engine of a vehicle, which engine is designed to carry out a preferred embodiment of the method according to the invention.

FIG. 2 schematically shows, in the manner of a circuit diagram, part of a starting device for an internal combustion engine of a vehicle, which engine is designed to carry out a preferred embodiment of the method according to the invention.

FIG. 3 schematically shows a preferred embodiment of the method according to the invention as a block diagram.

FIG. 4 schematically shows a voltage-time diagram that can be recorded in the course of a preferred embodiment of the method according to the invention.

### EMBODIMENT(S) OF THE INVENTION

In the drawings, the same reference signs denote the same or structurally identical elements.

In FIG. 1, a starting device 100 for an internal combustion engine 101 of a vehicle is shown schematically.

The starting device 100 has a starter pinion 102 which, in order to start the internal combustion engine 101, is brought into engagement with a ring gear 103 of the internal combustion engine. The starter pinion 102 is mounted axially displaceably on a shaft 104, as indicated by the double arrow, the starter pinion 102 being coupled to the shaft 104 for conjoint rotation. The starter pinion 102 is adjusted between a retracted inoperative position and a protruding engagement position with the ring gear 103 of the internal combustion engine 101 via a starter relay 120, which is electromagnetic and comprises two windings 121, 122 and a lifting armature 105 which, when current is supplied to the windings 121, 122, is drawn axially into these windings. The lifting armature 105 actuates an engagement lever 106, which acts on an engagement spring 107 seated on a driver 108 of a roller freewheel. The starter pinion 102 is coupled to the driver 108 on the output side, so that the axial advance movement of the driver 108 is converted into the desired axial adjusting movement of the starter pinion 102 between the inoperative position and the engagement position.

The rotating drive movement on the shaft 104 or the starter pinion 102 is generated by means of an electric starter motor 110 which is coupled to the shaft 104 via a gear 109, for example a planetary gear. When the electric starter motor 110 is actuated, the shaft 104 and thus also the starter pinion 102 are set in rotation.

The starter motor 110 is switched on via a switch-on device 123 which is integrated in the starter relay 120. The circuit is closed in the switch-on device 123 by means of a switching element, which is designed as a switching armature and is adjusted when the windings 121, 122 are energized. When the circuit is closed, the starter motor 110 is set in motion and the shaft 104 and the starter pinion 102 are driven rotatingly. An electronic pilot control relay 130 or an ignition switch (not shown) can be provided for controlling the starter relay 120 and the starter motor 110.

FIG. 2 shows part of the starting device 100 in the manner of a circuit diagram. As shown in FIG. 2, the pilot control relay 130 comprises a first switching element 131 for controlling the first winding 121 and a second switching element 132 for controlling the second winding 122.

The switching elements 131, 132 are each designed as a semiconductor output stage, for example each as a MOSFET. The pilot control relay 130 further comprises a computing unit 133 which is designed, for example, as a microcontroller and is in data-transmitting connection with a control device 140 of the vehicle via a communication system 135, for example CAN.

The first switching element 131 can be connected to the first winding 121 via a connection 161, for example via a terminal 50k. The second switching element 132 can be connected to the second winding 122 via a connection 162, for example a terminal 50i.

The first winding 121 is designed in particular as a pull-in winding and is connected to the starter motor 110. The second winding 122 is designed in particular as a hold-in winding and is also connected to ground via a connection 164, e.g. a terminal 31.

The switch-on device 123 is connected to a vehicle battery 150 via a connection 163, for example a terminal 30. The reference sign 151 denotes an internal resistance of the battery 150, and the reference sign 152 denotes a lead resistance of leads between the vehicle battery 150 and the starting device 100.

Using the starting device 100, a state of charge of the vehicle battery 150 can be determined within the scope of the present method. For this purpose, the microcontroller 133 is configured, in particular in terms of programming, to carry out a preferred embodiment of a method according to the invention, which is shown schematically in FIG. 3 as a block diagram and will be explained below.

In a step 301, the microcontroller 133 receives a request for determining the state of charge from the control device 140 via the communication system 135.

In step 302, the microcontroller 133 carries out an admissibility check as to whether the determination of the state of charge is permissible in the current status of the vehicle. If the request is assessed as impermissible, for example during a starting process or when the starter motor 110 is coasting down, there is a wait in step 303 for the duration of a predetermined time interval and then another check is carried out to determine whether the request is now permissible. If the admissibility check is positive, the state of charge of vehicle battery 150 is determined. For this purpose, the first winding 121 is controlled in step 304 by means of the first switching element 131 in a first control state and in particular is not energized. In this case, the open-circuit voltage or the on-board electrical system voltage between the terminal 30 (connection 163) and the terminal 31 (e.g. on the housing or the connection 164) is determined as a first voltage value U_{30.0}.

In step 305, the first winding 121 is then energized with high frequency in a clocked manner by means of the first switching element 131 in a second control state, with a first pulse duty factor of 50:50, for example, so that a current through the first winding 121 of approximately 100 A is set.

In step 306, there is a wait until the current has built up through the first winding 121.

Then, in step 307, the on-board electrical system voltage between the terminal 30 (connection 163) and the terminal 31 (connection 164) is again determined as a second voltage value U_{30.A}.

With a total internal resistance of a 24 V on-board electrical system, for example in the range between 5 mΩ and 8 mΩ in the case of a fully charged, warm vehicle battery, a load with a current through the first winding of 100 A leads, for example, to a voltage drop between 0.5 V and 0.8 V, which can expediently be detected with sufficient resolution, e.g. by means of an analog-to-digital converter of the pilot control relay.

The first winding 121 is then energized in step 308 in an unclocked manner by means of the first switching element 131 in a third control state, with a second pulse duty factor of 100%, for example. In particular, this produces a current through the first winding 121 of approximately 200 A.

In step 309, there is again a wait until the current has built up through the winding 121.

In step 310, a third voltage value U_{30.B} and a fourth voltage value U_{EW} are then determined. The on-board electrical system voltage between the terminal 30 (connection 163) and the terminal 31 (connection 164) is again determined as the third voltage value U_{30.B}. The voltage currently applied to the first winding 121 is determined as the fourth voltage value U_{EW}, for example between the terminals 31 (connection 164) and 50k (connection 161).

In step 311 the energization of the first winding 121 is ended and in step 312 the determined voltage values are evaluated. As part of this, an internal resistance of the on-board electrical system is determined as the resistance value R_{ges} depending on the second voltage value U_{30.A}, the third voltage value U_{30.B} and the fourth voltage value U_{EW}.

In particular, the following correlations apply to the determination of the resistance value R_{ges}:

ΔU=U_{30.A}−U_{30.B}=R_{ges}·I_{EW}

The following correlation applies to the current l_{EW} through the first winding:

$${I}_{EW} = \frac{{U}_{EW}}{{R}_{EW}}$$

This results in:

$${R}_{ges} = \frac{{U}_{EW}}{{R}_{EW} \cdot ( {U}_{30. A} - {U}_{30. B} )}$$

R_{EW} is the internal resistance of the first winding 121, which in a first approximation can be viewed as constant and is for example 100 mΩ. In particular, this internal resistance R_{EW} is known from the design and material characteristics.

Furthermore, the resistance value R_{ges} is corrected by a calibration value which corresponds to the lead resistance 152 of the leads between the vehicle battery 150 and the starting device 100. This calibration value can be determined, for example, in the course of starting up the vehicle and stored in a non-volatile memory of the microcontroller 133. In particular, the resistance value R_{ges} corrected by the calibration value corresponds to the internal resistance 151 of the vehicle battery 150.

In step 313, the corrected resistance value R_{ges} and the first voltage value U_{30.0} are now fed back from the microcontroller 133 via the communication system 135 to the control device 140 as the current state of charge of the vehicle battery 150. In step 314, the microcontroller 133 ends the function of determining the state of charge.

FIG. 4 schematically shows a voltage-time diagram that can be recorded in the course of a preferred embodiment of the method according to the invention. By way of example, FIG. 4 shows a time profile of the on-board electrical system voltage U between the terminals 30 (connection 163) and 31 (connection 164) plotted against time t.

At a point in time t₁, the first winding 121 is not energized according to the first control state and the first voltage value U_{30.0} is determined according to step 304.

From the point in time t₂ the winding 121 is controlled according to step 305 in the course of the second control state, whereupon the on-board electrical system voltage drops from the first voltage value U_{30.0} to the second voltage value U_{30.A}. The second voltage value U_{30.A} is determined at the point in time t₃ according to step 307.

At the point in time t₄, the winding 121 begins to be energized in the course of the third control state according to step 308, whereupon the on-board electrical system voltage drops from the second to the third voltage value U_{30.B}. The third voltage value U_{30.B} is determined at the point in time t₅ according to step 310. The energization of the winding 121 is ended at the point in time t₆.

1. Method for determining a state of charge of a vehicle battery (150) of a vehicle,
wherein a starter relay (120) of a starting device (100) for an internal combustion engine (101) of the vehicle for engaging a starter pinion (102) in a ring gear (103) of the internal combustion engine (101) has a first winding (121) and a second winding (122) which can be controlled independently of one another,
controlling the first winding (121) in predetermined control states (304, 305, 308) and determining voltage values that are established in the course of these control states (304, 307, 310) and
determining the state of charge of the vehicle battery (150) depending on the determined voltage values.

2. Method according to claim 1, comprising
not energizing (304) the first winding (121) in the course of a first control state and
energizing the first winding (121) in the course of a second and third control state in different ways (305, 308) in each case.

3. Method according to claim 2, comprising
not energizing the first winding (121) in the course of the first control state and determining (304) a first voltage value (U_{30.0}),
energizing the first winding (121) with a first current level in the course of the second control state (305) and determining (307) a second voltage value (U_{30.A}),
energizing the first winding (121) with a second current level (308) in the course of the third control state and determining (310) a third voltage value (U_{30.B}) and a fourth voltage value and
determining (312) the state of charge of the vehicle battery (150) depending on the first voltage value (U_{30.0}), the second voltage value (U_{30.A}), the third voltage value (U_{30.B}) and the fourth voltage value.

4. Method according to claim 3, comprising
determining a resistance value depending on the second voltage value (U_{30.A}), the third voltage value (U_{30.B}) and the fourth voltage value and determining (312) the state of charge of the vehicle battery (150) depending on the first voltage value (U_{30.0}) and on the resistance value.

5. Method according to claim 2, comprising generating different current levels by different pulse duty factors of the battery voltage on the winding.

6. Method according to claim 5, comprising energizing (305) the first winding (121) with high frequency in a clocked manner during the course of the second control state and in an unclocked manner during the course of the third control state (308).

7. Method according to claim 2, comprising energizing the first winding (121) in the course of the second control state and the third control state such that in the course of the second control state, a current through the first winding (121) is set, the current strength of which is lower than in the course of the third control state (305, 308).

8. Method according to claim 1, comprising further determining the state of charge of the vehicle battery (150) depending on a predetermined calibration value (312) which characterizes a lead resistance (152).

9. Method according to claim 2, comprising further determining the state of charge of the vehicle battery (150) depending on a predetermined calibration value (312) which characterizes a lead resistance (152).

10. Method according to claim 1, comprising first carrying out (302) an admissibility check and if the admissibility check is positive, controlling the first winding (121) in the predetermined control states (304, 305, 308) and determining the state of charge of the vehicle battery (150) depending on the determined voltage values (312).

11. Method according to claim 2, comprising first carrying out (302) an admissibility check and if the admissibility check is positive, controlling the first winding (121) in the predetermined control states (304, 305, 308) and determining the state of charge of the vehicle battery (150) depending on the determined voltage values (312).

12. Method according to claim 1, wherein the first winding (121) is a pull-in winding and the second winding (122) is a hold-in winding.

13. Method according to claim 2, wherein the first winding (121) is a pull-in winding and the second winding (122) is a hold-in winding.

14. Method according to claim 1, comprising controlling the first winding (121) by means of first switching element (131), and controlling the second winding (122) by means of a second switching element (132).

15. Method according to claim 2, comprising controlling the first winding (121) by means of first switching element (131), and controlling the second winding (122) by means of a second switching element (132).

16. Method according to claim 14, wherein the first switching element (131) and the second switching element (132) are each implemented as an output stage, in particular each as a semiconductor switch, in particular each as a MOSFET.

17. Computing unit (133) which is configured to carry out all the method steps of a method according to claim 1.

18. Computer program which causes a computing unit (133) to carry out all the method steps of a method according to any of claims 1 when the program is executed on the computing unit (133).

19. Machine-readable storage medium having a computer program according to claim 18 stored thereon.
